(19) United States
(12) Patent Application Publication
(10) Pub. No.: US 2023/0420608 A1
(43) Pub. Date: Dec. 28, 2023

(54) ALL-NITRIDE-BASED EPITAXIAL STRUCTURE AND LIGHT-EMITTING DEVICE

(71) Applicant: Narvellux Technologies (ShenZhen) Co., LTD., Shenzhen (CN)

(72) Inventors: David YOUNG, Shenzhen (CN); Yanhao DU, Shenzhen (CN); Wei SUN, Shenzhen (CN); Anli YANG, Shenzhen (CN); Dawei NIE, Shenzhen (CN); Jingting HE, Shenzhen (CN); Zengliang ZHONG, Shenzhen (CN)

(21) Appl. No.: 18/236,413

(22) Filed: Aug. 22, 2023

(30) Foreign Application Priority Data
Jun. 22, 2022 (CN) 202210720731.8

(51) Int. Cl. H01L 33/06; H01L 33/32

(52) U.S. Cl. CPC H01L 33/06; H01L 33/32

(57) ABSTRACT

The present disclosure includes an all-nitride-based epitaxial and chip structure and a light-emitting device. The epitaxial and chip structure includes an N-type semiconductor layer, a P-type semiconductor layer, an electroluminescent (EL) multiple quantum wells (MQWs) region, and a first photoluminescent (PL) multiple quantum wells (MQWs) region stacked on a main surface of a substrate. The EL MQWs region generates a first-color light by an EL method and the first-color light is further transmitted to the first PL MQWs region or/and the second PL MQWs region where the second-color light or/and the third-color light are generated by a PL method. The present disclosure provides an EL MQWs region to generate the first-color light, and also provides a first, a second or more PL MQWs regions to further convert the first-color light into the second, the third or more-color lights which allow RGB or multiple colors emission.

### CROSS-REFERENCE TO RELATED APPLICATIONS

This application claims priority to Chinese Patent Application No. 202210720731.8, filed on Jun. 22, 2022 in the National Intellectual Property Administration of China, the contents of which are herein incorporated by reference in their entireties.

### TECHNICAL FIELD

The present disclosure relates to the field of semiconductor optoelectronics, and in particular to an all-nitride-based epitaxial structure and a light-emitting device.

### BACKGROUND

The Gallium Nitride (GaN)-based white LED (light-emitting diodes) offers benefits, such as energy savings, extended service life and small size, and is now widely used in backlighting, automotive lamps and other lighting fields. As GaN-based long-wavelength LED currently has problems with low luminous efficiency, efficiency droop and the blue shift of emission peak, a common method to achieve white LED is to combine the GaN-based blue chip with orange phosphor. However, white light produced by this method has relatively low color rendering index, and also comes with problems such as uneven chromaticity and performance degradation.

In addition, Micro LED, as the next generation of full-color display technology, needs to be achieved by clustering high-density tiny LED chips, in colors of red, green and blue, in array on a screen. Therefore, transferring a massive amount of red, green and blue LED chips in multiple times has become the main technical bottleneck restricting the development of Micro LED. If the GaN-based LED chips, in colors of red, green and blue, can be integrally grown on the same chip, the complexity in producing end products can be significantly reduced.

### SUMMARY OF THE DISCLOSURE

A first embodiment of the present disclosure may provide an all-nitride-based epitaxial and chip structure. The all-nitride-based epitaxial and chip structure may include an N-type semiconductor layer, a P-type semiconductor layer, an electroluminescent (EL) multiple quantum wells (MQWs) region, and a first photoluminescent (PL) multiple quantum wells (MQWs) region stacked on a main surface of a substrate. The N-type semiconductor layer and the P-type semiconductor layer may be disposed on two sides of the EL MQWs region respectively. Holes from the P-type semiconductor layer and electrons from the N-type semiconductor layer may recombine in the EL MQWs region, generating first-color light by an EL method; the first-color light may be further transmitted to the first PL MQWs region where second-color light is generated by a PL method.

In some embodiments, the epitaxial and chip structure may further include a P-type electrode. The P-type electrode may be disposed on a side of the P-type semiconductor layer away from the EL MQWs region. The P-type electrode may be a reflective electrode with/without a conductive reflection layer underneath.

In some embodiments, holes from the P-type semiconductor layer may be configured not to reach the first PL MQWs region.

In some embodiments, the thickness of the EL MQWs region may be configured in a way that holes from the P-type semiconductor layer cannot reach the first PL MQWs region.

In some embodiments, the epitaxial and chip structure may further include a separation layer disposed between the EL MQWs region and the first PL MQWs region. The separation layer may be configured to block the holes from the P-type semiconductor layer from reaching the first PL MQWs region.

In some embodiments, the separation layer may be an N-type semiconductor material.

In some embodiments, the EL MQWs region and the first PL MQWs region may be sandwiched between the N-type semiconductor layer and the P-type semiconductor layer.

In some embodiments, the EL MQWs region and the first PL MQWs region may be disposed on two sides of the N-type semiconductor layer respectively.

In some embodiments, the EL MQWs region and the first PL MQWs region may include quantum wells of InGaN or InGaAlN respectively. The In content in the quantum wells of the EL MQWs region may be less than that of the first PL MQWs region.

In some embodiments, the N-type semiconductor layer may include a first semiconductor sub-layer and a second semiconductor sub-layer, or the P-type semiconductor layer may include a first semiconductor sub-layer and a second semiconductor sub-layer. The first PL MQWs region may be sandwiched between the first semiconductor sub-layer and the second semiconductor sub-layer.

In some embodiments, the epitaxial and chip structure may further include a spectral-reflection enhancement structure. The spectral-reflection enhancement structure may be disposed on a side of the first PL MQWs region away from the EL MQWs region. The spectral-reflection enhancement structure may be configured to reflect first-color light that is not absorbed by the first PL MQWs region back into the first PL MQWs region, and meantime to allow the second-color light to pass through the spectral-reflection enhancement structure.

In some embodiments, the first PL MQWs region may be configured to convert a portion of the first-color light into the second-color light, and the second-color light may further be mixed with the remaining portion of the first-color light to form the third-color light.

In some embodiments, the epitaxial and chip structure may further include a second PL MQWs region. The first-color light and/or the second-color light may be transmitted to the second PL MQWs region, generating the third-color light by the PL method. The reflective electrode or the conductive reflection layer may also be configured to reflect the second-color light and/or the third-color light.

In some embodiments, the second PL MQWs region and the first PL MQWs region may be disposed on a side of the EL MQWs region; or the second PL MQWs region and the first PL MQWs region may be disposed on the two sides of the EL MQWs region respectively.

In some embodiments, wavelengths of the first-color light may be in a range of 360 nm-460 nm.

In some embodiments, the wavelengths of the first-color light may be in a range of 360 nm-420 nm, and wavelengths of the second-color light may be in a range of 420 nm-480 nm; or the wavelengths of the first-color light may be in a range of 420 nm-480 nm, and the wavelengths of the second-color light may be in a range of 490 nm-550 nm; or the wavelengths of the first-color light may be in a range of 490 nm-550 nm, and the wavelengths of the second-color light may be in a range of 560 nm-650 nm.

In some embodiments, the epitaxial and chip structure may include a normal face-up structure, a flip-chip structure, a vertical chip structure, or a thin film structure with the substrate removed.

In some embodiments, the epitaxial and chip structure may further include a N-type electrode. The N-type electrode may be disposed on a side of the N-type semiconductor layer away from the substrate.

In some embodiments, the spectral-reflection enhancement structure may be made of a reflector or a reflective film.

Another embodiment of the present disclosure may provide a light-emitting device, including an epitaxial and chip structure and a phosphor. The epitaxial and chip structure may include an N-type semiconductor layer, a P-type semiconductor layer, an EL MQWs region, and a first PL MQWs region stacked on a main surface of a substrate. The N-type semiconductor layer and the P-type semiconductor layer may be disposed on two sides of the EL MQWs region respectively; holes from the P-type semiconductor layer and electrons from the N-type semiconductor layer may recombine in the EL MQWs region, generating first-color light by an EL method; the first-color light may be further transmitted to the first PL MQWs region where second-color light may be generated by a PL method. The phosphor may be disposed on a light-emitting surface of the epitaxial and chip structure. The first-color light and/or the second-color light may be transmitted to the phosphor where another color light is generated.

### BRIEF DESCRIPTION OF THE DRAWINGS

In order to clearly illustrate the technical solutions in some embodiments of the present disclosure, the drawings corresponding to the embodiments will be briefly introduced as below. Apparently, the following drawings are merely based on some embodiments of the present disclosure. For any ordinary skilled in the art, many derivative drawings can be obtained from the following drawings without any creative work.

FIG. 1 is a schematic view of an epitaxial and chip structure according to a first embodiment in the present disclosure.

FIG. 2 is a schematic view of an epitaxial and chip structure according to a second embodiment in the present disclosure.

FIG. 3 is a schematic view of an epitaxial and chip structure according to a third embodiment in the present disclosure.

FIG. 4 is a schematic view of an epitaxial and chip structure according to a fourth embodiment in the present disclosure.

FIG. 5 is a schematic view of an epitaxial and chip structure according to a fifth embodiment in the present disclosure.

FIG. 6 is a schematic view of an epitaxial and chip structure according to a sixth embodiment in the present disclosure.

FIG. 7 is a spectrum diagram of the epitaxial and chip structure in the present disclosure.

FIG. 8 is a diagram comparing the blue shift of peak wavelength of EP-LED in the present disclosure to a traditional green LED.

FIG. 9 is a schematic view of an epitaxial and chip structure according to a seventh embodiment in the present disclosure.

FIG. 10 is a schematic view of an epitaxial and chip structure according to an eighth embodiment in the present disclosure.

FIG. 11 is a schematic view of an epitaxial and chip structure according to a ninth embodiment in the present disclosure.

FIG. 12 is a schematic view of an epitaxial and chip structure according to a tenth embodiment in the present disclosure.

FIG. 13 is a schematic view of a light-emitting device according to an eleventh embodiment in the present disclosure.

### DETAILED DESCRIPTION

In order to make the skilled in the art better understand the technical solutions in the present disclosure, some embodiments along with the drawings will further explain an all-nitride-based epitaxial and chip structure and a light-emitting device provided in the present disclosure in details. Obviously, the following described embodiments are merely some examples rather than all possible embodiments. According to the embodiments mentioned in the present disclosure, any other embodiments obtained by the skilled in the art without creative work are in the scope of the present disclosure.

Terms, such as “first” and “second”, used in the present disclosure aim to distinguish between different objects and are not intended to describe any particular order. In addition, terms, such as “comprising”, “having” and any similar variations, are intended to cover non-exclusive inclusion. For example, a process, a method, a system, a product or an apparatus that comprises a series of steps or units is not limited to the listed steps or units. Instead, it optionally also includes steps or units that are not listed; other steps or units that are inherent to the process, the method, the product or the apparatus may be optionally included as well.

The present disclosure provides an all-nitride-based epitaxial structure, in order to solve the current technical problems of light produced via an external light converter such as phosphor. The problems include low color conversion efficiency, low luminous intensity, and loss and degradation of phosphor luminescence, which further lead to the problem of low luminous efficiency of current techniques.

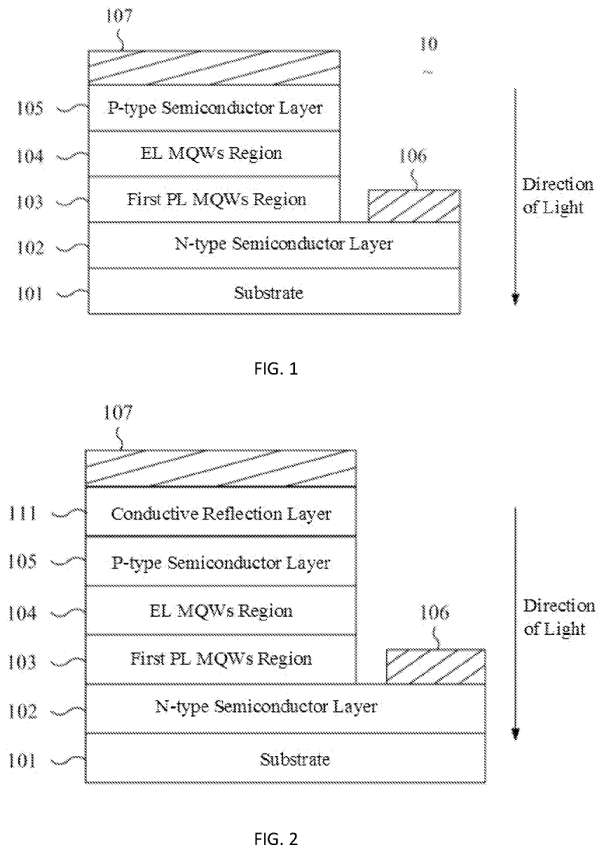

As shown in FIG. 1 which is a schematic view of an epitaxial and chip structure according to a first embodiment in the present disclosure. According to FIG. 1, an epitaxial structure 10 may include a substrate 101, an N-type semiconductor layer 102, a P-type semiconductor layer 105, an EL MQWs region 104, and a first PL MQWs region 103.

Specifically, the N-type semiconductor layer 102, the P-type semiconductor layer 105, the EL MQWs region 104, and the first PL MQWs region 103 may be stacked on a side of the substrate 101 and on a main surface of the substrate 101. The N-type semiconductor layer 102 and the P-type semiconductor layer 105 may be disposed on two sides of the EL MQWs region 104 respectively, and the first PL MQWs region 103 may be disposed on a side of the EL MQWs region 104 away from the P-type semiconductor layer 105. In some embodiments, the first embodiment may not limit a deposition order of the N-type semiconductor layer 102, the P-type semiconductor layer 105, the EL MQWs region 104, and the first PL MQWs region 103, as long as an arrangement of the above-mentioned layers is satisfied.

In some embodiments, in the first embodiment, the substrate 101 may be a double-polished sapphire substrate with a thickness in a range of 10 μm-1000 μm.

In some embodiments, the P-type semiconductor layer 105 in the first embodiment may include a p-AlGaN layer and a p-GaN layer. The p-AlGaN layer and the p-GaN layer may grow in sequence on the EL MQWs region 104. The p-AlGaN layer may have a thickness in a range of and the p-GaN layer may have a thickness in a range of 10 nm-500 nm.

Holes from the P-type semiconductor layer 105 and electrons from the N-type semiconductor layer 102 may recombine in the EL MQWs region 104, generating the first-color light by an EL method. In some embodiments, wavelengths of the first-color light in the first embodiment may be in a range of 360 nm-460 nm. The first-color light may be further transmitted to the first PL MQWs region 103 where the second-color light is generated by a PL method. In some embodiments, the In contents in the EL MQWs region 104 and the first PL MQWs region 103 may be tuned in order to generate lights of corresponding colors.

Specifically, the EL MQWs region 104 and the first PL MQWs region 103 may include quantum wells of InGaN or InGaAlN. The In content in the quantum wells of the EL MQWs region 104 may be less than that of the first PL MQWs region 103. In some embodiments, the In content in the quantum wells of the EL MQWs region 104 may be in a range of 0-20%, and the In content in the quantum wells of the first PL MQWs region 103 may be in a range of 12%-50%.

The thickness of the EL MQWs region 104 may be in a range of 5 nm-1000 nm, and the thickness of the first PL MQWs region 103 may be in a range of 5 nm-200 nm. The EL MQWs region 104 and the first PL MQWs region 103 may include at least one quantum well and at least one quantum barrier. A thickness of the quantum well may be in a range of 0.5 nm-10 nm and the thickness of the quantum barrier may be in a range of 3 nm-100 nm. In some embodiments, each of the EL MQWs region 104 and the first PL MQWs region 103 may be a multi-periodic structure. One quantum well and one quantum barrier may cooperatively form a pair of the periodic structure. The EL MQWs region 104 may have 1-15 periods, i.e., 1-15 pairs of quantum wells and quantum barriers. The first PL MQWs region 103 may have a period number of 1-100 periods, i.e., 1-100 pairs of quantum wells and quantum barriers.

Alternatively, in some other embodiments, the first PL MQWs region 103 may only convert a portion of the first-color light into the second-color light, and the second-color light may be further mixed with the remaining portion of the first-color light to form a third-color light.

Alternatively, in the present embodiment, the wavelengths of the first-color light may be in a range of 360 nm-420 nm and the wavelengths of the second-color light may be in a range of 420 nm-480 nm; or the wavelengths of the first-color light may be in a range of 420 nm-480 nm, and the wavelengths of the second-color light may be in a range of 490 nm-550 nm; or the wavelengths of the first-color light may be in a range of 490 nm-550 nm, and the wavelengths of the second-color light may be in a range of 560 nm-650 nm. Since the first-color light and the second-color light share similar wavelengths, the first-color light of short wavelengths may be converted into the second-color light of long wavelengths more efficiently, and a loss of energy during the wavelength conversion may be reduced.

As shown in FIG. 1, the epitaxial and chip structure 10 provided in the first embodiment may further include a P-type electrode 107 and an N-type electrode 106. The P-type electrode 107 may be disposed on a side of the P-type semiconductor layer 105 away from the EL MQWs region 104 for holes generation in the P-type semiconductor layer 105, and the N-type electrode 106 may be disposed on a side of the N-type semiconductor layer 102 away from the substrate 101 for electrons generation in the N-type semiconductor layer 102.

Specifically, in the present embodiment, the P-type electrode 107 may be a reflective electrode. A portion of the first-color light generated by the EL MQWs region 104 may be directly transmitted to the first PL MQWs region 103, while the other portion of the first-color light generated by the EL MQWs region 104 may be transmitted to the P-type electrode 107 where it can be reflected back into the first PL MQWs region 103 as well. Therefore, the first PL MQWs region 103 may receive most of the first-color light generated by the EL MQWs region 104 so that the color-conversion efficiency of the first PL MQWs region 103 can be effectively enhanced, and the luminous efficiency of the epitaxial and chip structure 10 can be improved. Meanwhile, the first PL MQWs region 103 may convert the first-color light into the second-color light and emit the second-color light outside the epitaxial and chip structure 10 through the substrate 101 which may be transparent.

The thickness of the P-type semiconductor layer 105 and the thickness of the EL MQWs region 104 may be configured to prevent the holes from the P-type semiconductor layer 105 from reaching the first PL MQWs region 103. In this way, the first PL MQWs region 103 may not produce light by an EL method, and the spectrum of the second-color light produced by the first PL MQWs region 103 may not be broadened, which improves the quality of the light produced by the epitaxial and chip structure 10.

The thickness of the P-type electrode 107 may be in a range of 10 nm-1000 nm and the thickness of the N-type electrode 106 may be in a range of 10 nm-1000 nm. In some embodiments, the P-type electrode 107 and the N-type electrode 106 may each be metals. The P-type electrode 107 may include one of or a combination of several metals, such as titanium, aluminum, silver, gold, nickel, platinum; and the N-type electrode 106 may include one of or a combination of several metals, such as titanium, aluminum, silver, gold, nickel, platinum.

As shown in FIG. 2 based on FIG. 1, FIG. 2 may be a schematic view of an epitaxial and chip structure according to a second embodiment in the present disclosure. As shown in FIG. 2, an epitaxial and chip structure 10 provided in the second embodiment may include a substrate 101, an N-type semiconductor layer 102, a P-type semiconductor layer 105, an EL MQWs region 104, a first PL MQWs region 103, a P-type electrode 107, an N-type electrode 106, and a conductive reflection layer 111 disposed between the P-type electrode 107 and the P-type semiconductor layer 105.

Specifically, the N-type semiconductor layer 102, the first PL MQWs region 103, the EL MQWs region 104, the P-type semiconductor layer 105, the conductive reflection layer 111, and the P-type electrode 107 may be stacked on a side of the substrate 101 in sequence, where the N-type semiconductor layer 102 may be closest to the substrate 101 and the P-type electrode 107 may be farthest from the substrate 101. The N-type electrode 106 may be disposed on a side of the N-type semiconductor layer 102 away from the substrate 101.

The conductive reflection layer 111 may reflect the first-color light, generated by the EL MQWs region 104 back into the first PL MQWs region 103, in order to further improve a color-conversion efficiency of the first PL MQWs region 103 as well as a luminous efficiency of the epitaxial and chip structure 10.

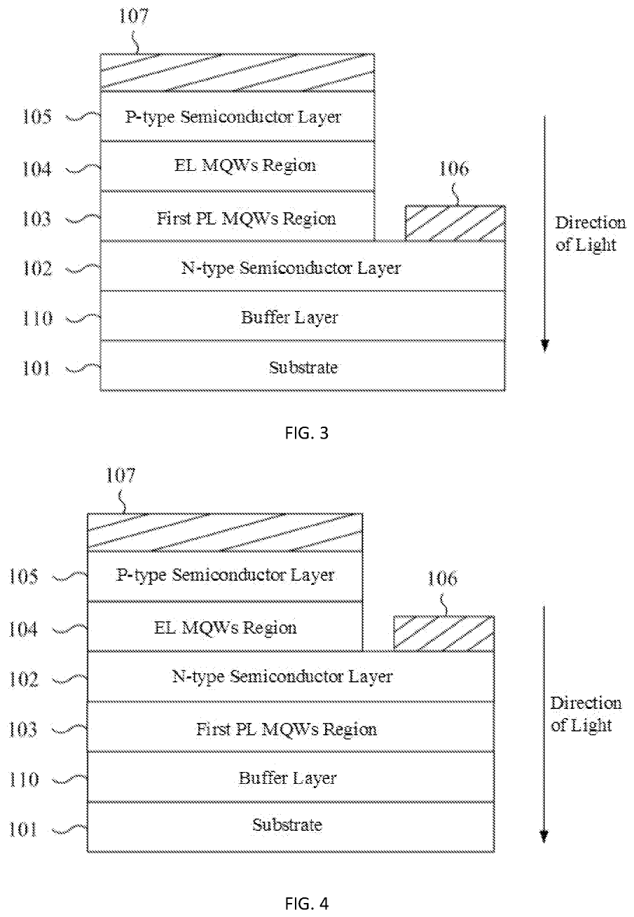

As shown in FIG. 3 based on FIG. 1, FIG. 3 may be a schematic view of an epitaxial structure according to a third embodiment in the present disclosure. As shown in FIG. 3, an epitaxial structure 10 provided in the third embodiment may include a substrate 101, a buffer layer 110, an N-type semiconductor layer 102, a P-type semiconductor layer 105, an EL MQWs region 104, a first PL MQWs region 103, a P-type electrode 107, and an N-type electrode 106. The buffer layer 110 may be disposed between the substrate 101 and the N-type semiconductor layer 102.

Specifically, the buffer layer 110, the N-type semiconductor layer 102, the first PL MQWs region 103, the EL MQWs region 104, the P-type semiconductor layer 105, and the P-type electrode 107 may be stacked on a side of the substrate 101 in sequence, where the buffer layer 110 may be the closest to the substrate 101 and the P-type electrode 107 may be the farthest from the substrate 101. The N-type electrode 106 may be disposed on a side of the N-type semiconductor layer 102 away from the substrate 101.

Alternatively, in some other embodiments, the buffer layer 110 may be a GaN nucleation layer, and the thickness of the GaN nucleation layer may be in a range of 5 nm-200 nm.

Specifically, in the present embodiment, the EL MQWs region 104 and the first PL MQWs region 103 may be sandwiched between the N-type semiconductor layer 102 and the P-type semiconductor layer 105. In the present embodiment, electrons from the N-type semiconductor layer 102 may be transmitted to the EL MQWs region 104 through the first PL MQWs region 103, and holes from the P-type semiconductor layer 105 may be transmitted to the EL MQWs region 104 where electrons and holes recombine and give out light. The thickness of the P-type semiconductor layer 105 and the thickness of the EL MQWs region 104 may be configured to prevent the holes from the P-type semiconductor layer 105 from reaching the first PL MQWs region 103.

As shown in FIG. 4 based on FIG. 1 and FIG. 3, FIG. 4 may be a schematic view of an epitaxial and chip structure according to a fourth embodiment in the present disclosure. As shown in FIG. 4, an epitaxial and chip structure 10 provided in the fourth embodiment may include a substrate 101, a buffer layer 110, a first PL MQWs region 103, an N-type semiconductor layer 102, a P-type semiconductor layer 105, an EL MQWs region 104, a P-type electrode 107, and an N-type electrode 106.

Specifically, the buffer layer 110, the first PL MQWs region 103, the N-type semiconductor layer 102, the EL MQWs region 104, the P-type semiconductor layer 105, and the P-type electrode 107 may be stacked on a side of the substrate 101 in sequence, where the buffer layer 110 may be the closest to the substrate 101 and the P-type electrode 107 may be the farthest from the substrate 101. The N-type electrode 106 may be disposed on a side of the N-type semiconductor layer 102 away from the substrate 101.

The EL MQWs region 104 and the first PL MQWs region 103 may be disposed on the sides of the N-type semiconductor layer 102. Electrons from the N-type semiconductor layer 102 and holes from the P-type semiconductor layer 105 may be directly transmitted to the EL MQWs region 104 so that electrons and holes may recombine in the EL MQWs region 104. Furthermore, the thickness of the P-type semiconductor layer 105, the thickness of the EL MQWs region 104 and the thickness of the N-type semiconductor layer 102 may be configured to prevent holes from the P-type semiconductor layer 105 from reaching the first PL MQWs region 103.

Optionally in the fourth embodiment, the epitaxial and chip structure 10 may further include an undoped-GaN layer. The undoped-GaN layer may be disposed between the first PL MQWs region 103 and the buffer layer 110. A thickness of the undoped-GaN layer may be in a range of 100 nm-10000 nm.

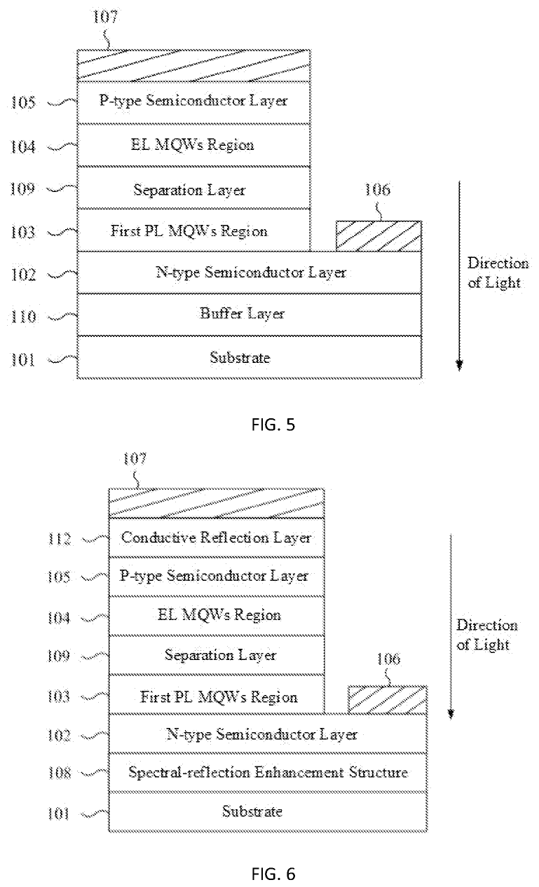

As shown in FIG. 5 based on FIG. 1 and FIG. 3, FIG. 5 may be a schematic view of an epitaxial and chip structure according to a fifth embodiment in the present disclosure. As shown in FIG. 5, an epitaxial and chip structure 10 provided in the fifth embodiment may include a substrate 101, a buffer layer 110, an N-type semiconductor layer 102, a first PL MQWs region 103, a separation layer 109, a P-type semiconductor layer 105, an EL MQWs region 104, a P-type electrode 107, and an N-type electrode 106. The separation layer 109 may be disposed between the EL MQWs region 104 and the first PL MQWs region 103. The separation layer 109 may be configured to block the holes from the P-type semiconductor layer 105 from reaching the first PL MQWs region 103.

Specifically, the buffer layer 110, the N-type semiconductor layer 102, the first PL MQWs region 103, the separation layer 109, the EL MQWs region 104, the P-type semiconductor layer 105, and P-type electrode 107 may be stacked on a side of the substrate 101 in sequence, where the buffer layer 110 may be the closest to the substrate 101 and the P-type electrode 107 may be the farthest from the substrate 101. The N-type electrode 106 may be disposed on a side of the N-type semiconductor layer 102 away from the substrate 101.

In the fifth embodiment, electrons from the N-type semiconductor layer 102 may be transmitted to the EL MQWs region 104 through the first PL MQWs region 103 and the separation layer 109. Holes from the P-type semiconductor layer 105 may be transmitted to the EL MQWs region 104 as well so that electrons may recombine with holes in the EL MQWs region 104. Meanwhile, the thickness of the P-type semiconductor layer 105, the thickness of the EL MQWs region 104 and the thickness of the separation layer 109 may be configured to prevent the holes from the P-type semiconductor layer 105 from reaching the first PL MQWs region 103.

In some embodiments, the separation layer 109 provided in the fifth embodiment may be made of an N-type semiconductor material such as an n-GaN layer, and the thickness of the separation layer 109 may be in a range of 100 nm-10000 nm.

As shown in FIG. 6 based on FIG. 2 and FIG. 5, FIG. 6 may be a schematic view of an epitaxial and chip structure according to a sixth embodiment in the present disclosure. As shown in FIG. 6, an epitaxial and chip structure 10 provided in the sixth embodiment may include a substrate 101, a spectral-reflection enhancement structure 108, an N-type semiconductor layer 102, a first PL MQWs region 103, a separation layer 109, a P-type semiconductor layer 105, an EL MQWs region 104, a conductive reflection layer 111, a P-type electrode 107, and an N-type electrode 106. The spectral-reflection enhancement structure 108 may be disposed on a side of the first PL MQWs region 103 away from the EL MQWs region 104, specifically between the substrate 101 and the N-type semiconductor layer 102. The spectral-reflection enhancement structure 108 may be configured to reflect first-color light that may not be absorbed by the first PL MQWs region 103 back into the first PL MQWs region 103, and configured to allow the second-color light generated by the first PL MQWs region 103 to pass through.

Specifically, the spectral-reflection enhancement structure 108, the N-type semiconductor layer 102, the first PL MQWs region 103, the separation layer 109, the EL MQWs region 104, the P-type semiconductor layer 105, the conductive reflection layer 111, and the P-type electrode 107 may be stacked on a side of the substrate 101 in sequence, where the spectral-reflection enhancement structure 108 may be the closest to the substrate 101 and the P-type electrode 107 may be the farthest from the substrate 101. The N-type electrode 106 may be disposed on a side of the N-type semiconductor layer 102 away from the substrate 101. In some embodiments, the spectral-reflection enhancement structure 108 may be moved to the other side of the substrate 101 with the N-type semiconductor layer 102 contacting the substrate 101.

In the sixth embodiment, electrons from the N-type semiconductor layer 102 may be transmitted to the EL MQWs region 104 through the first PL MQWs region 103 and the separation layer 109. Holes from the P-type semiconductor layer 105 may be transmitted to the EL MQWs region 104 as well so that electrons and holes may recombine in the EL MQWs region 104. Furthermore, the thickness of the P-type semiconductor layer 105, the thickness of the EL MQWs region 104, and the thickness of the separation layer 109 may be configured accordingly to prevent holes from the P-type semiconductor layer 105 from reaching the first PL MQWs region 103.

Specifically, the spectral-reflection enhancement structure 108 in the sixth embodiment, may reflect the first-color light emitted from the EL MQWs region 104 and meantime allow the second-color light generated from the first PL MQWs region 103 to pass through. In some embodiments, the spectral-reflection enhancement structure 108 in the sixth embodiment may be a reflector or a reflective film, or the like.

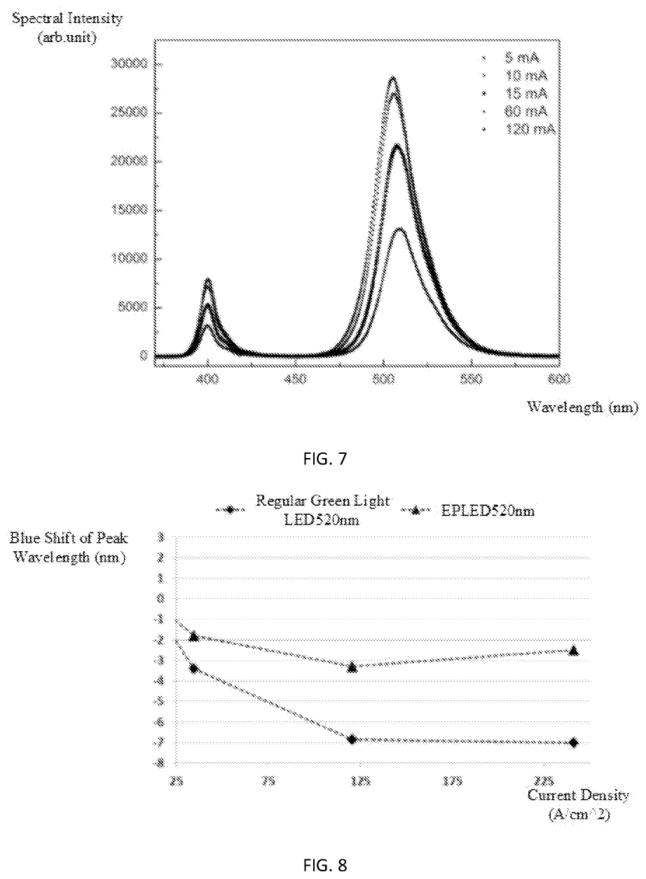

As shown in FIG. 7 and FIG. 8 based on FIG. 6, FIG. 7 is a spectrum example of the epitaxial and chip structure in the present disclosure. FIG. 8 is a diagram comparing the blue shift of peak wavelength of EP-LED in the present disclosure to a traditional green LED.

As shown in FIG. 7, center wavelengths of the first-color light generated by the EL MQWs region 104 in the epitaxial and chip structure 10 of the present disclosure may be approximately 400 nm, and center wavelengths of second-color light generated by the first PL MQWs region 103 may be approximately 520 nm. Furthermore, as shown in FIG. 7, the spectral intensity of the second-color light may be much greater than that of the first-color light. That is to say, the first PL MQWs region 103 may absorb at least a majority of the first-color light and convert the first-color light into the second-color light.

As shown in FIG. 7, the second-color light in the sixth embodiment may be specifically the green light. Furthermore, as shown in FIG. 8, when the epitaxial and chip structure 10 in the sixth embodiment and a traditional green LED are operating at same current densities, the blue shift of the peak wavelength of the green light emitted by the epitaxial and chip structure 10 may be smaller than that of a traditional green LED. That is to say, the epitaxial and chip structure 10, named by EP-LED, in the sixth embodiment may effectively solve an issue of the blue shift in long-wavelength traditional EL LEDs, and the issue of efficiency droop in long-wavelength EL LEDs may be also solved accordingly.

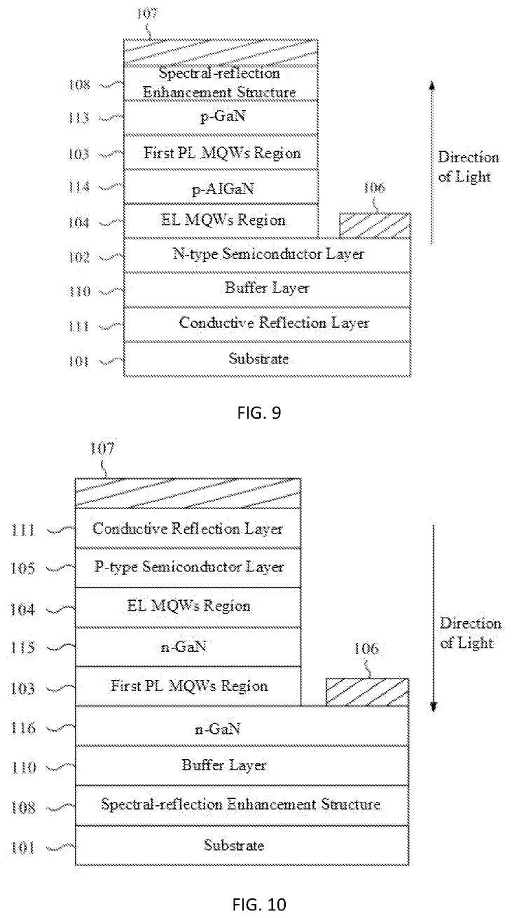

As shown in FIG. 9 based on FIG. 2, FIG. 3 and FIG. 6, FIG. 9 may be a schematic view of the seventh embodiment of the epitaxial and chip structure in the present disclosure. As shown in FIG. 9, an epitaxial and chip structure 10 in the seventh embodiment may include a substrate 101, a buffer layer 110, a spectral-reflection enhancement structure 108, an N-type semiconductor layer 102, a first PL MQWs region 103, a P-type semiconductor layer 105, an EL MQWs region 104, a conductive reflection layer 111, a P-type electrode 107, and an N-type electrode 106.

The P-type semiconductor layer 105 may include a first semiconductor sub-layer 113 and a second semiconductor sub-layer 114. The first PL MQWs region 103 may be sandwiched between the first semiconductor sub-layer 113 and the second semiconductor sub-layer 114. Specifically, the first semiconductor sub-layer 113 may be a p-GaN layer and the second semiconductor sub-layer 114 may be a p-AlGaN layer.

Specifically, the conductive reflection layer 111, the buffer layer 110, the N-type semiconductor layer 102, the EL MQWs region 104, the second semiconductor sub-layer 114, the first PL MQWs region 103, the first semiconductor sub-layer 113, the spectral-reflection enhancement structure 108, and the P-type electrode 107 may be stacked on a side of the substrate 101 in sequence, where the conductive reflection layer 111 may be the closest to the substrate 101 and the P-type electrode 107 may be the farthest from the substrate 101. The N-type electrode 106 may be disposed on a side of the N-type semiconductor layer 102 away from the substrate 101. In some embodiments, the conductive reflection layer 111 may be moved to the other side of the substrate 101 with the buffer layer 110 contacting the substrate 101.

In the present embodiment, electrons from the N-type semiconductor layer 102 may be transmitted to the EL MQWs region 104. Holes from the first semiconductor sub-layer 113 may be transmitted to the EL MQWs region 104 through the first PL MQWs region 103 and the second semiconductor sub-layer 114. Holes from the second semiconductor sub-layer 114 may be transmitted to the EL MQWs region 104 as well. Therefore, Holes from the first semiconductor sub-layer 113 and electrons from the second semiconductor sub-layer 114 may recombine in the EL MQWs region 104. Furthermore, the current density applied to the P-type electrode 107 and the N-type electrode 106 may be tuned to prevent the electrons from the N-type semiconductor layer 102 from reaching the first PL MQWs region 103.

As shown in FIG. 10 based on FIG. 2, FIG. 3 and FIG. 6, FIG. 10 may be a schematic view of the eighth embodiment of the epitaxial and chip structure in the present disclosure. As shown in FIG. 10, an epitaxial and chip structure 10 in the eighth embodiment may include a substrate 101, a buffer layer 110, a spectral-reflection enhancement structure 108, an N-type semiconductor layer 102, a first PL MQWs region 103, a P-type semiconductor layer 105, an EL MQWs region 104, a conductive reflective layer 111, a P-type electrode 107, and an N-type electrode 106.

The N-type semiconductor layer 102 may include a first semiconductor sub-layer 115 and a second semiconductor sub-layer 116. The first PL MQWs region 103 may be sandwiched between the first semiconductor sub-layer 115 and the second semiconductor sub-layer 116. Specifically, each of the first semiconductor sub-layer 115 and the second semiconductor sub-layer 116 may be an n-GaN layer.

Specifically, the spectral-reflection enhancement structure 108, the buffer layer 110, the second semiconductor sub-layer 116, the first PL MQWs region 103, the first semiconductor sub-layer 115, the EL MQWs region 104, the P-type semiconductor layer 105, the conductive reflection layer 111, and the P-type electrode 107 may be stacked on a side of the substrate 101 in sequence, where the spectral-reflection enhancement structure 108 may be the closest to the substrate 101 and the P-type electrode 107 may be the farthest from the substrate 101. The N-type electrode 106 may be disposed on a side of the N-type semiconductor layer 102 away from the substrate 101. In some embodiments, the spectral-reflection enhancement structure 108 may be moved to the other side of the substrate 101 with the buffer layer 110 contacting the substrate 101.

In the present embodiment, holes from the P-type semiconductor layer 105 may be transmitted to the EL MQWs region 104. Electrons from the first semiconductor sub-layer 115 may be transmitted to the EL MQWs region 104, and electrons from the second semiconductor sub-layer 116 may be transmitted to the EL MQWs region 104 through the first PL MQWs region 103 and the first semiconductor sub-layer 115. In this way, holes from the P-type semiconductor layer 105, electrons from the first semiconductor sub-layer 115 and the second semiconductor sub-layer 116 may recombine in the EL MQWs region 104. Furthermore, the thickness of the P-type semiconductor layer 105, the thickness of the EL MQWs region 104 and the thickness of the first semiconductor sub-layer 115 may be configured to prevent holes from the P-type semiconductor layer 105 from reaching the first PL MQWs region 103.

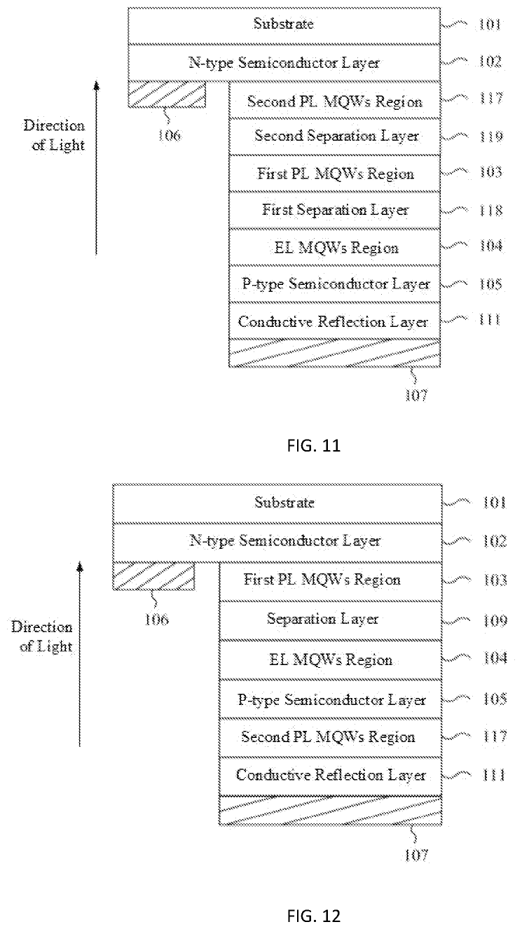

As shown in FIG. 11 based on FIG. 2 and FIG. 5, FIG. 11 may be a schematic view of an epitaxial and chip structure according to a ninth embodiment in the present disclosure. As shown in FIG. 11, an epitaxial and chip structure 10 in the ninth embodiment may include a substrate 101, an N-type semiconductor layer 102, a P-type semiconductor layer 105, a first PL MQWs region 103, a second PL MQWs region 117, an EL MQWs region 104, a conductive reflection layer 111, a first separation layer 118, a second separation layer 119, a P-type electrode 107, and an N-type electrode 106. The second PL MQWs region 117 and the first PL MQWs region 103 may be disposed on a side of the EL MQWs region 104.

The first-color light generated by the EL MQWs region 104 and/or second-color light generated by the first PL MQWs region 103 may both be transmitted to the second PL MQWs region 117 where the third-color light is generated by a PL method.

Specifically, the N-type semiconductor layer 102, the second PL MQWs region 117, the second separation layer 119, the first PL MQWs region 103, the first separation layer 118, the EL MQWs region 104, the P-type semiconductor layer 105, the conductive reflection layer 111, and the P-type electrode 107 may be stacked on a side of the substrate 101 in sequence, where the N-type semiconductor layer 102 may be the closest to the substrate 101 and the P-type electrode 107 may be the farthest from the substrate 101. The N-type electrode 106 may be disposed on a side of the N-type semiconductor layer 102 away from the substrate 101.

The conductive reflection layer 111 may also reflect the second-color light generated by the first PL MQWs region 103 and/or third-color light generated by the second PL MQWs region 117.

In the present embodiment, electrons from the N-type semiconductor layer 102 may be transmitted to the EL MQWs region 104 through the second PL MQWs region 117, the second separation layer 119, the first PL MQWs region 103, and the first separation layer 118. Holes from the P-type semiconductor layer 105 may also be transmitted to the EL MQWs region 104. Electrons from the N-type semiconductor layer 102 and holes from the P-type semiconductor layer 105 may recombine in the EL MQWs region 104. Furthermore, the thickness of the P-type semiconductor layer 105, the thickness of the EL MQWs region 104, the thickness of the first separation layer 118, the thickness of the first PL MQWs region 103, the thickness of the second separation layer 119, and the thickness of the second PL MQWs region 117 may be configured to prevent the at least one holes output from the P-type semiconductor layer 105 from being transmitted to the first PL MQWs region 103.

Alternatively, some other embodiments may provide only the first separation layer 118 between the first PL MQWs region 103 and the EL MQWs region 104. Therefore, the second separation layer 119 may not be disposed between the second PL MQWs region 117 and the first PL MQWs region 103. The thickness of the P-type semiconductor layer 105, the thickness of the EL MQWs region 104, the thickness of the first separation layer 118, the thickness of the first PL MQWs region 103, and the thickness of the second PL MQWs region 117 may be configured to prevent holes from the P-type semiconductor layer 105 from reaching the first PL MQWs region 103.

Alternatively, in some other embodiments, the first PL MQWs region 103 may include one or more combinations of the following MQWs pairs, including n₁ pairs of In_{y(1)}Ga_{1-y(1)}N/GaN, n₂ pairs of In_{y(2)}Ga_{1-y(2)}N/GaN, . . . , and nₖ pairs of In_{y(k)}Ga_{1-y(k)}N/GaN. A sum of the n₁, the n₂, . . . , and the nₖ may be n, and the n may represent a total number of periodic pair. The value of n may be in a range of 1-100. Y(k) may be less than the In content in the quantum well of the EL MQWs region 104, and the value of y(k) may be in a range of 0.12-0.5.

As shown in FIG. 12 based on FIG. 2 and FIG. 5, FIG. 12 may be a schematic view of the tenth embodiment of the epitaxial and chip structure in the present disclosure. As shown in FIG. 12, an epitaxial and chip structure 10 in the tenth embodiment may include a substrate 101, an N-type semiconductor layer 102, a P-type semiconductor layer 105, a first PL MQWs region 103, a second PL MQWs region 117, and an EL MQWs region 104, the conductive reflection layer 111, the separation layer 109, the P-type electrode 107, and the N-type electrode 106. The second PL MQWs region 117 may be disposed on a side of the EL MQWs region 104 and the first PL MQWs region 103 may be disposed on the other side of the EL MQWs region 104.

Specifically, the N-type semiconductor layer 102, the first PL MQWs region 103, the separation layer 109, the EL MQWs region 104, the P-type semiconductor layer 105, the second PL MQWs region 117, the conductive reflection layer 111, and the P-type electrode 107 may be stacked on a side of the substrate 101 in sequence, where the N-type semiconductor layer 102 may be the closest to the substrate 101 and the P-type electrode 107 may be the farthest from the substrate 101. The N-type electrode 106 may be disposed on a side of the N-type semiconductor layer 102 away from the substrate 101. The conductive reflection layer 111 may be configured to totally reflect the second-color light generated by the first PL MQWs region 103, the third-color light generated by the second PL MQWs region 117, and first-color light generated by the EL MQWs region 104.

In the present embodiment, electrons from the N-type semiconductor layer 102 may be transmitted to the EL MQWs region 104 through the second PL MQWs region 117 and the separation layer 109. Holes from the P-type semiconductor layer 105 may also be transmitted to the EL MQWs region 104 where electrons and holes may recombine. Furthermore, the thickness of the P-type semiconductor layer 105, the thickness of the EL MQWs region 104, and the thickness of the separation layer 109 may be configured to prevent holes from the P-type semiconductor layer 105 from reaching the first PL MQWs region 103. In addition, the thickness of the N-type semiconductor layer 102, the thickness of the first PL MQWs region 103, the thickness of the separation layer 109, the thickness of the EL MQWs region 104, and the thickness of the separation layer 109 can be configured to prevent electrons from the N-type semiconductor layer 102 from reaching the second PL MQWs region 117.

Specifically, in the first six embodiments, the eighth embodiment, the ninth embodiment and the tenth embodiment of the present disclosure, structures of the epitaxial and chip structure 10 illustrated are all a flip-chip structure. The structure of the epitaxial and chip structure 10 illustrated in the seventh embodiment is a normal face-up structure. Alternatively, in some other embodiments, an epitaxial structure 10 may take a vertical structure or a thin-film structure with the substrate 101 removed. Also, the layer structures mentioned in the first to tenth embodiments may be freely combined and designed based on actual needs to achieve the corresponding face-up structure, the flip-chip structure, the vertical structure, or the thin-film structure. The removal of the substrate 101 from the thin-film structure may not affect the growth sequence of the multilayer structure contained in the epitaxial and chip structure 10.

The present disclosure may provide an EL MQWs region 104 by an EL method in an epitaxial and chip structure 10 to generate the first-color light. In addition, and the present disclosure may also provide a first PL MQWs region 103 by a PL method to further convert the first-color light to the second-color light. In this way, the first PL MQWs region 103 may receive most of the first-color light generated by the EL MQWs region 104 and convert it into the second-color light. Thus, the color-conversion efficiency of the epitaxial and chip structure 10 may be effectively enhanced.

Furthermore, in the present disclosure, the first PL MQWs region 103 rather than phosphor give out another color light. This phosphor-free structure can solve the issue of the loss and degradation regarding to light-emitting devices with phosphor, thus improving the luminous efficiency of the epitaxial and chip structure 10. In the present disclosure, traditional EL long-wavelength LEDs may be replaced by the first PL MQWs region 103 to solve the problems of efficiency droop caused by applying a voltage and the issue of spectral blue shift. Moreover, the present embodiment may achieve a multi-wavelength integrated excitation by a single-chip epitaxial structure 10, and further create a RGB display pixel or a RGB white light source. In this way, the epitaxial and chip structure 10 may meet the design requirements of Micro LEDs and reduce the complexity in the production of end products.

In addition, any combination of the N-type semiconductor layer 102, the first PL MQWs region 103, the separation layer 109, the EL MQWs region 104, the P-type semiconductor layer 105, the conductive reflection layer 111, and the P-type electrodes 107 may be stacked on a side of the substrate 101 in sequence based on the present disclosure. That is to say, a growth may be performed on one side of the substrate 101. In this way, a growth on both sides of the substrate 101 may be avoided since a second growth may cause damage and adverse effects to the structure formed by the first growth. For example, a second growth of a high-temperature GaN may cause a significantly negative affect to the crystal quality of a quantum well formed by the first growth, resulting in a malfunction of the device. Furthermore, the epitaxial and chip structure 10 of the present disclosure may be obtained by a growth on one side of the substrate 101 so that production cost may be reduced, and the yield may be improved.

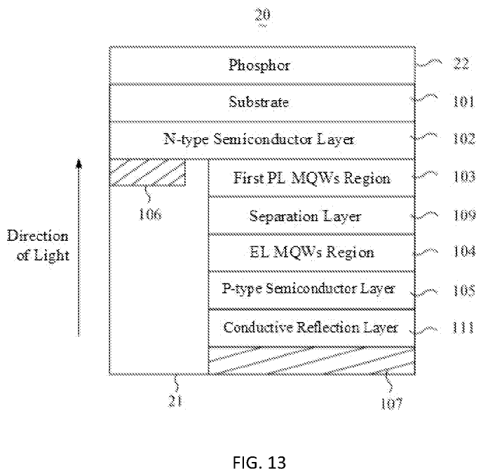

The present disclosure may also provide a light-emitting device, as shown in FIG. 13. FIG. 13 may be a schematic view of the eleventh embodiment of the epitaxial and chip structure in the present disclosure. As shown in FIG. 13, a light-emitting device 20 may include an epitaxial structure 21 and a phosphor 22. The epitaxial and chip structure 21 may be an epitaxial structure described in any of an embodiment mentioned previously.

Specifically, the phosphor 22 may be disposed on the light-emitting surface of the epitaxial and chip structure 21. The first-color light generated by an EL MQWs region 104 of the epitaxial and chip structure 21 and/or second-color light generated by a first PL MQWs region 103 of the epitaxial and chip structure 21 may be transmitted to the phosphor 22 so that the phosphor 22 may be stimulated to generate the fourth-color light.

The first-color light may be further mixed with both the second-color light and the fourth-color light to form the fifth-color light. In some embodiments, the first-color light may be blue light, the second-color light may be green light, the fourth-color light may be red light, and the mixed fifth-color light may be white light.

The above-mentioned embodiments are only some examples from the present disclosure and they are not intended to limit the scope of the present disclosure. Any equivalent structure or equivalent process transformation according to the contents of the specification of the present disclosure and the accompanying drawings of the present disclosure may also be included in the scope of patent protection of this present disclosure. In addition, directly or indirectly applying the contents of the specification of the present disclosure and the accompanying drawings of the present disclosure in other related fields of technology may be under the scope of patent protection of this present disclosure as well.

What is claimed is:

1. An all-nitride-based epitaxial and chip structure, comprising: an N-type semiconductor layer, a P-type semiconductor layer, an electroluminescent (EL) multiple quantum wells (MQWs) region, and a first photoluminescent (PL) multiple quantum wells (MQWs) region stacked on a main surface of a substrate, wherein the N-type semiconductor layer and the P-type semiconductor layer are disposed on two sides of the EL MQWs region respectively; holes from the P-type semiconductor layer and electrons from the N-type semiconductor layer recombine in the EL MQWs region, generating first-color light by an EL method; the first-color light is further transmitted to the first PL MQWs region where second-color light is generated by a PL method.

2. The epitaxial and chip structure according to claim 1, further comprising a P-type electrode, wherein the P-type electrode is disposed on a side of the P-type semiconductor layer away from the EL MQWs region; the P-type electrode is a reflective electrode with/without a conductive reflection layer underneath.

3. The epitaxial and chip structure according to claim 1, wherein the holes from the P-type semiconductor layer are configured not to reach the first PL MQWs region.

4. The epitaxial and chip structure according to claim 3, wherein the thickness of the EL MQWs region is configured in a way that holes from the P-type semiconductor layer cannot reach the first PL MQWs region.

5. The epitaxial and chip structure according to claim 3, comprising a separation layer disposed between the EL MQWs region and the first PL MQWs region, wherein the separation layer is configured to block the holes from the P-type semiconductor layer from reaching the first PL MQWs region.

6. The epitaxial and chip structure according to claim 5, wherein the separation layer is an N-type semiconductor material.

7. The epitaxial and chip structure according to claim 1, wherein the EL MQWs region and the first PL MQWs region are sandwiched between the N-type semiconductor layer and the P-type semiconductor layer.

8. The epitaxial and chip structure according to claim 1, wherein the EL MQWs region and the first PL MQWs region are disposed on two sides of the N-type semiconductor layer respectively.

9. The epitaxial and chip structure according to claim 1, wherein the EL MQWs region and the first PL MQWs region comprises quantum wells of InGaN or InGaAlN respectively; the In content in the quantum wells of the EL MQWs region is less than that of the first PL MQWs region.

10. The epitaxial and chip structure according to claim 1, wherein the N-type semiconductor layer comprises a first semiconductor sub-layer and a second semiconductor sub-layer, or the P-type semiconductor layer comprises a first semiconductor sub-layer and a second semiconductor sub-layer; and the first PL MQWs region is sandwiched between the first semiconductor sub-layer and the second semiconductor sub-layer.

11. The epitaxial and chip structure according to claim 1, further comprising a spectral-reflection enhancement structure, wherein the spectral-reflection enhancement structure is disposed on a side of the first PL MQWs region away from the EL MQWs region; the spectral-reflection enhancement structure is configured to reflect the first-color light that is not absorbed by the first PL MQWs region back into the first PL MQWs region, and meantime to allow the second-color light to pass through the spectral-reflection enhancement structure.

12. The epitaxial and chip structure according to claim 1, wherein the first PL MQWs region is configured to convert a portion of the first-color light into the second-color light; and the second-color light is further mixed with the remaining portion of the first-color light forming a third-color light.

13. The epitaxial and chip structure according to claim 2, further comprising a second PL MQWs region, wherein the first-color light and/or the second-color light is/are transmitted to the second PL MQWs region, generating the third-color light by the PL method; the reflective electrode or the conductive reflection layer is configured to reflect the second-color light and/or the third-color light.

14. The epitaxial and chip structure according to claim 13, wherein the second PL MQWs region and the first PL MQWs region are disposed on a side of the EL MQWs region; or
the second PL MQWs region and the first PL MQWs region are disposed on the two sides of the EL MQWs region respectively.

15. The epitaxial and chip structure according to claim 14, wherein wavelengths of the first-color light are in a range of 360 nm-460 nm.

16. The epitaxial and chip structure according to claim 14, wherein the wavelengths of the first-color light are in a range of 360 nm-420 nm, and wavelengths of the second-color light are in a range of 420 nm-480 nm; or
the wavelengths of the first-color light are in a range of 420 nm-480 nm, and the wavelengths of the second-color light are in a range of 490 nm-550 nm; or
the wavelengths of the first-color light are in a range of 490 nm-550 nm, and the wavelengths of the second-color light are in a range of 560 nm-650 nm.

17. The epitaxial and chip structure according to claim 1, comprising a normal face-up structure, a flip-chip structure, a vertical chip structure, or a thin film structure with the substrate removed.

18. The epitaxial and chip structure according to claim 1, further comprising a N-type electrode, wherein the N-type electrode is disposed on a side of the N-type semiconductor layer away from the substrate.

19. The epitaxial and chip structure according to claim 11, wherein the spectral-reflection enhancement structure is made of a reflector or a reflective film.

20. A light-emitting device, comprising
an epitaxial and chip structure comprising:
an N-type semiconductor layer,
a P-type semiconductor layer,
an EL MQWs region, and
a PL MQWs region stacked on a main surface of a substrate;
wherein the N-type semiconductor layer and the P-type semiconductor layer are disposed on two sides of the EL MQWs region respectively; holes from the P-type semiconductor layer and electrons from the N-type semiconductor layer recombine in the EL MQWs region, generating first-color light by an EL method; the first-color light is further transmitted to the first PL MQWs region where second-color light is generated by a PL method; and
a phosphor;
wherein the phosphor is disposed on a light-emitting surface of the epitaxial and chip structure; the first-color light and/or the second-color light are transmitted to the phosphor where another color light is generated.
